(19) United States
(12) Patent Application Publication
(10) Pub. No.: US 2026/0194686 A1
(43) Pub. Date: Jul. 9, 2026

(54) METHOD AND APPARATUS FOR DETERMINING SCALE SEQUENCE OF HELIUM RESOURCES, AND DEVICE

(71) Applicant: China National Petroleum Corporation, Beijing (CN)

(72) Inventors: Yiping Wu, Beijing (CN); Lirong Dou, Beijing (CN); Shizhen Tao, Beijing (CN); Zhanxiang Lei, Beijing (CN); Qian Li, Beijing (CN)

(21) Appl. No.: 18/861,498

(22) PCT Filed: Dec. 16, 2022
(86) PCT No.: PCT/CN2022/139580

§ 371 Date: Oct. 29, 2024

(30) Foreign Application Priority Data
May 18, 2022 (CN) 202210551884.4

(51) Int. Cl. G01V 11/00; G06F 30/28

(52) U.S. Cl. CPC G01V 11/00; G06F 30/28

(57) ABSTRACT

Disclosed in the present disclosure are a method and apparatus for determining a scale sequence of helium resources, and a device. The method includes: acquiring helium contents of different plays in known gas reservoirs in a target research area, to determine helium reserves of a helium reservoir with known helium content and helium reserves of respective plays of the helium reservoir in the known gas reservoirs; determining helium reserves of the respective plays of the helium reservoirs in the known gas reservoirs; determining a likelihood function distribution of the helium reserves of the respective plays of all the helium reservoirs in the target research area, based on the helium reserves of the respective plays of the helium reservoirs, to simulate and construct an accumulative gas reservoir model of all the helium reservoirs in the target research area.

### RELATED APPLICATION

The present disclosure claims the priority of the Chinese invention patent application with an application number of 202210551884.4 filed on May 18, 2022, the disclosure of which is incorporated herein by reference.

### TECHNICAL FIELD

The present disclosure relates to the technical field of helium resources evaluation, and particularly to a method and apparatus for determining a scale sequence of helium resources, and a device.

### BACKGROUND

In China, the helium resources account for 1.8% of those in the world, while the helium output accounts for only 0.3% of that in the world. The dependency on foreign countries is extremely high (the current data shows that the dependency is more than 95%), and the helium resources have become strategic resources in urgent need. At present, it has become an important research object for persons skilled in the art to find out the potentials and the distributions of the helium resources in key areas at home and abroad through the evaluation of the helium resources, optimize the favorable enrichment area and ensure the national energy source security. The inventor finds that although helium and natural gas are stored in the same trap, the genesis, the accumulation and the resource distribution characteristics of helium have nothing to do with the natural gas resources, and the formation, the migration and the accumulation of helium have their own laws. Currently at home and abroad, there is no mature evaluation method of the helium resources.

At present, the helium percentage method and the genetic method are mainly used to calculate the reserves and the resource quantity of helium. For example, Zhang Fuli, et al. (2012) determined that the Weihe basin is rich in helium according to the composition characteristics of water-soluble gas in the basin, and based on the fact that the Yanshanian uranium-rich granite was determined as the main source of helium through a helium isotope analysis, the resource quantity of water-soluble helium was calculated using a helium-containing water-soluble gas calculation method and an uranium radioactive decay calculation method. Zhang Zuoxiang, et al. discussed the evaluation method of the helium resources in natural gas, and put forward that the volume method, the Monte Carlo method, the residual hydrocarbon method, the thermal simulation method, the grey system prediction method, the reservoir scale sequence method and the dynamic method were mainly used to predict the natural gas resources in China, and then the helium content test result of the found helium fields is multiplied by the resource quantity of natural gas to calculate the resource quantity of helium. J. Richard Bowersox (2019) introduced the evaluation of the helium resources in central Kentucky, USA, and pointed out that the minimum standard of helium content in the evaluation of the local helium resources is 0.2% (which was considered to have a commercial value). It is considered that helium is similar to oil and gas resources in terms of migration and accumulation, and there are almost the same factors for trapped reservoir-formation. In which, for the “source rock”, attention should be paid to the contents of uranium and thorium in the rock stratum, and the currently used reference standard of the natural gamma logging value is 120 to 108 API. The lithology of the source rock is mainly shale, and the gamma radioactivity contour map is drawn accordingly. Based on the calculation of the volume of the helium-producing source rock, the model established by Brown (2010) is used to analyze the contents of uranium and thorium in the helium-producing source rock within 500 Ma to form the genesis-based evaluation result of the helium resources, and the final result is obtained by further considering the reservoir porosity within 10%.

### SUMMARY

The inventor finds that although the helium percentage method is accurate in calculation, it depends on the number and quality of helium data points and the accuracy of natural gas reserves. Meanwhile, the calculation error of helium source rock volume is very large and the reliability of resource evaluation results is low. Therefore, the helium percentage method and the genetic method have a limited application scope and are difficult to be widely used. The inventor also finds that although helium and natural gas are gathered in the same trap, as can be seen from the helium content in natural gas in a research area and the comparison of helium distribution trends in some gas reservoirs, there is no direct correlation between the natural gas reserve and the helium reserve distribution, and instead, the helium content and the reserve distribution of the helium reservoirs have their own laws.

In view of the above problems, the present disclosure is proposed to provide a method and apparatus for determining a scale sequence of helium resources, and a device, so as to overcome or at least partially solve the above problems.

In a first aspect, an embodiment of the present disclosure provides a method for determining a scale sequence of helium resources, which may include:
acquiring helium contents of different plays in known gas reservoirs in a target research area, to determine helium reserves of a helium reservoir with known helium content and helium reserves of respective plays of the helium reservoir in the known gas reservoirs;
determining helium reserves of a helium reservoir with unknown helium content and helium reserves of respective plays of the helium reservoir in the known gas reservoirs, based on the helium reserves of the helium reservoir with known helium content and the helium reserves of respective plays of the helium reservoir in the known gas reservoirs;
determining helium reserves of the respective plays of the helium reservoirs in the known gas reservoirs in the target research area, based on the helium reserves of the respective plays of the helium reservoir with known helium content in the known gas reservoirs and the helium reserves of the respective plays of the helium reservoir with unknown helium content in the known gas reservoirs;
determining a likelihood function distribution of the helium reserves of the respective plays of all the helium reservoirs in the target research area, based on the helium reserves of the respective plays of the helium reservoirs, to simulate and construct an accumulative gas reservoir model of the target research area; and
performing a statistical simulation based on the accumulative gas reservoir model to obtain all the helium reservoirs and the helium reserves of the helium reservoirs in the target research area, so as to determine a scale sequence of helium resources.

Optionally, the acquiring helium contents of different plays in known gas reservoirs in a target research area, to determine helium reserves of a helium reservoir with known helium content and helium reserves of respective plays of the helium reservoir in the known gas reservoirs includes:
acquiring the helium contents of different plays in the known gas reservoirs in the target research area; and
determining the helium reserves of the helium reservoir with known helium content and the helium reserves of the respective plays of the helium reservoir in the known gas reservoirs using a percentage method, based on the helium contents of different plays in the known gas reservoirs in the target research area and natural gas reserves of the known gas reservoirs.

Optionally, the determining helium reserves of a helium reservoir with unknown helium content and helium reserves of respective plays of the helium reservoir in the known gas reservoirs, based on the helium reserves of the helium reservoir with known helium content and the helium reserves of the respective plays of the helium reservoir in the known gas reservoirs includes:
acquiring gas reservoir data of a same oil and gas field and/or a neighboring oil and gas field with similar plays of a gas reservoir with unknown helium content in the known gas reservoirs; wherein the gas reservoir data of the same oil and gas field and/or the neighboring oil and gas field includes: a natural gas reserve and a percentage of helium content in the gas reservoir;
determining a helium reservoir similarity coefficient of respective plays of a gas reservoir with known helium content in the known gas reservoirs and the gas reservoirs in the same oil and gas field and/or the neighboring oil and gas field; and
performing analogy to determine the helium reserves of the helium reservoir with unknown helium content and the helium reserves of the respective plays of the helium reservoir in the known gas reservoirs, based on the gas reservoir data of the same oil and gas field and/or the neighboring oil and gas field and the helium reservoir similarity coefficient.

Optionally, before the acquiring gas reservoir data of a same oil and gas field and/or a neighboring oil and gas field with similar plays of a gas reservoir with unknown helium content in the known gas reservoirs, the method further includes:
analyzing reservoir formation characteristics of helium reservoirs for the respective plays with unknown helium contents in the known gas reservoirs, to determine gas reservoirs with reservoir formation characteristics similar to those of the respective plays with unknown helium contents in the known gas reservoirs.

Optionally, the determining a likelihood function distribution of the helium reserves of the respective plays of all the helium reservoirs in the target research area, based on the helium reserves of the respective plays of the helium reservoirs, to simulate and construct an accumulative gas reservoir model of the target research area includes:
determining a likelihood function distribution of the helium reserves of the respective plays of all the helium reservoirs in the target research area, based on the helium reserves of the known helium reservoirs and the helium reserves of the respective plays of the known helium reservoirs;
determining minimum and maximum reservoir formation scales of the helium reservoirs in the target research area, based on the likelihood function distribution of the helium reserves of the respective plays of all the helium reservoirs in the target research area; and
inputting the minimum and maximum reservoir formation scales of the helium reservoirs into a Pareto distribution function to simulate and construct an accumulative gas reservoir model of the target research area.

Optionally, after the inputting the minimum and maximum reservoir formation scales of the helium reservoirs into a Pareto distribution function to simulate and construct an accumulative gas reservoir model of the target research area, the method further includes:
assigning least square weight values to a distribution parameter, the maximum reservoir formation scale and the number of the plays of the helium reservoirs in the Pareto distribution function, so as to increase the weight of influence of large-scale helium reservoirs in the accumulative gas reservoir model on the accumulative gas reservoir model.

Optionally, the inputting the minimum and maximum reservoir formation scales of the helium reservoirs into a Pareto distribution function, and simulating and constructing an accumulative gas reservoir model of the target research area includes:
inputting the minimum and maximum reservoir formation scales of the helium reservoirs into a Pareto distribution function;
presetting a predetermined number of maximum helium reservoir accumulation areas as the distribution parameter of the distribution of the helium reservoirs;
simulating the Pareto distribution function to identify the helium reservoirs and the helium reserves in a number greater than the predetermined number in the target research area; and
simulating and constructing the accumulative gas reservoir model of the target research area, based on the identified helium reservoirs and the helium reserves of the identified helium reservoirs.

Optionally, after the identifying the helium reservoirs and the helium reserves in a number greater than the predetermined number in the target research area, the method further includes:

sorting and numbering the identified helium reservoirs based on the helium reserves of the identified helium reservoirs, so as to simulate and construct the accumulative gas reservoir model.

Optionally, performing a statistical simulation based on the accumulative gas reservoir model to obtain all the helium reservoirs and the helium reserves thereof in the target research area, so as to determine a scale sequence of helium resources includes:
performing a statistical simulation using a Monte Carlo simulation method based on the accumulative gas reservoir model, to obtain all the helium reservoirs in the target research area and the helium reserves of all the helium reservoirs; all the helium reservoirs in the target research area and the helium reserves thereof comprising: helium reservoirs and helium reserves thereof within the maximum reservoir formation scale, as well as unknown helium reservoirs and resource quantities of helium under different probability conditions; and
obtaining the scale sequence of helium resources in the target research area based on the helium reservoirs and the helium reserves within the maximum reservoir scale, the unknown helium reservoirs and the resource quantities of helium under different probability conditions, and a preset probability value.

In a second aspect, an embodiment of the present disclosure provides an apparatus for determining a scale sequence of helium resources, which may include:
a data acquisition module configured to acquire helium contents of different plays in known gas reservoirs in a target research area;
a first determination module configured to determine helium reserves of a helium reservoir with known helium content and helium reserves of respective plays of the helium reservoir in the known gas reservoirs, based on the helium contents of different plays in the known gas reservoirs;
a second determination module configured to helium reserves of a helium reservoir with unknown helium content and helium reserves of respective plays of the helium reservoir in the known gas reservoirs, based on the helium reserves of the helium reservoir with known helium content and the helium reserves of respective plays of the helium reservoir in the known gas reservoirs;
a third determination module configured to determine helium reserves of the respective plays of the helium reservoirs in the known gas reservoirs in the target research area, based on the helium reserves of the respective plays of the helium reservoir with known helium content in the known gas reservoirs and the helium reserves of the respective plays of the helium reservoir with unknown helium content in the known gas reservoirs;
a simulation and construction module configured to determine a likelihood function distribution of the helium reserves of the respective plays of all the helium reservoirs in the target research area, based on the helium reserves of the respective plays of the helium reservoirs, to simulate and construct an accumulative gas reservoir model of the target research area; and
a statistical simulation module configured to perform a statistical simulation based on the accumulative gas reservoir model to obtain all the helium reservoirs and the helium reserves of the helium reservoirs in the target research area, so as to determine a scale sequence of helium resources.

In a third aspect, an embodiment of the present disclosure provides a computer-readable storage medium which stores a computer program, wherein when executed by a processor, the computer program implements the method for determining the scale sequence of helium resources according to the first aspect.

In a fourth aspect, an embodiment of the present disclosure provides a computer device, comprising a memory, a processor and a computer program which is stored in the memory and runnable on the processor, wherein when executing the computer program, the processor implements the method for determining the scale sequence of helium resources according to the first aspect.

The advantageous effects of the above technical solutions provided by the embodiments of the present disclosure are at least as follows:
The embodiments of the present disclosure provide a method and apparatus for determining a scale sequence of helium resources, and a device. In the method, firstly, the known gas reservoirs in the target research area are taken as the sample data, and after the helium contents of different plays in the known gas reservoirs are acquired, the helium reserves of the respective plays of the helium reservoir with known helium content in the known gas reservoirs are determined; during the data collection and the reserve prediction of the helium reservoirs, quantitative analysis is carried out with the respective plays, so that the prediction results are more accurate, and the accuracy of the helium resource evaluation is improved. Next, the helium reserves of the helium reservoir with unknown helium content and the helium reserves of the respective plays of the helium reservoir in the known gas reservoirs are determined based on the helium reserves of the helium reservoir with known helium content and the helium reserves of the respective plays of the helium reservoir in the known gas reservoirs, and the helium reserves of the respective plays of the helium reservoirs in the known gas reservoirs in the target research area are determined by summarization. Next, the accumulative gas reservoir model of the helium reservoirs in the target research area is simulated and constructed based on the known helium reservoirs, and finally, a statistical simulation is performed on the accumulative gas reservoir model to estimate the helium reservoirs and the helium reserves of the helium reservoirs in the unknown gas reservoirs in the target research area, so as to obtain the scale sequence of helium resources in the target research area. This method simulates and constructs the accumulative gas reservoir model, and then predicts the unknown helium reservoirs and the reserves thereof in the research area, which is helpful to analyze the potential and the distribution of the helium resources in the target research area, optimize the favorable enrichment area, and ensure the development and use of the helium resources. Further, this method may be used as a reliable basis for the evaluation of helium resources and helium assets, the long-term development planning of the helium-containing gas fields and the integration of the full industry chain of helium.

Additional features and advantages of the present disclosure will be set forth in the description which follows, and in part will be apparent from the description, or may be learned by practice of the present disclosure. The objectives and other advantages of the present disclosure may be realized and attained by the structure particularly pointed out in the description and drawings.

The technical solutions of the present disclosure will be described in further detail below through the drawings and embodiments.

### BRIEF DESCRIPTION OF THE DRAWINGS

The drawings, which are included to provide a further understanding of the present disclosure, constitute a part of the specification, and explain the present disclosure together with the embodiments of the present disclosure, without limiting the present disclosure. In the drawings:

FIG. 1 illustrates a flow diagram of a method for determining a scale sequence of helium resources according to an embodiment of the present disclosure;

FIG. 2 illustrates a specific flow diagram of step S11;

FIG. 3 illustrates a specific flow diagram of step S12;

FIG. 4 illustrates a specific flow diagram of step S14;

FIG. 5 illustrates a specific flow diagram of step S143;

FIG. 6 illustrates a specific flow diagram of step S15;

FIG. 7 illustrates an example of a free gas helium concentration histogram and

accumulative distribution map in a research area according to an embodiment of the present disclosure;

FIG. 8 illustrates a schematic diagram of a truncated Pareto distribution according to an embodiment of the present disclosure;

FIG. 9 illustrates a schematic diagram of an accumulative distribution of helium reservoirs according to an embodiment of the present disclosure; and

FIG. 10 illustrates a structural diagram of an apparatus for determining a scale sequence of helium resources according to an embodiment of the present disclosure.

### DETAILED DESCRIPTION OF THE EXEMPLARY EMBODIMENTS

The exemplary embodiments of the present disclosure will be described in more detail below with reference to the drawings. Although the exemplary embodiments of the present disclosure are illustrated in the drawings, it should be understood that the present disclosure may be embodied in various forms and should not be limited by the embodiments set forth herein. Rather, these embodiments are provided so that the present disclosure can be more thoroughly understood and the scope of the present disclosure can be fully conveyed to persons skilled in the art.

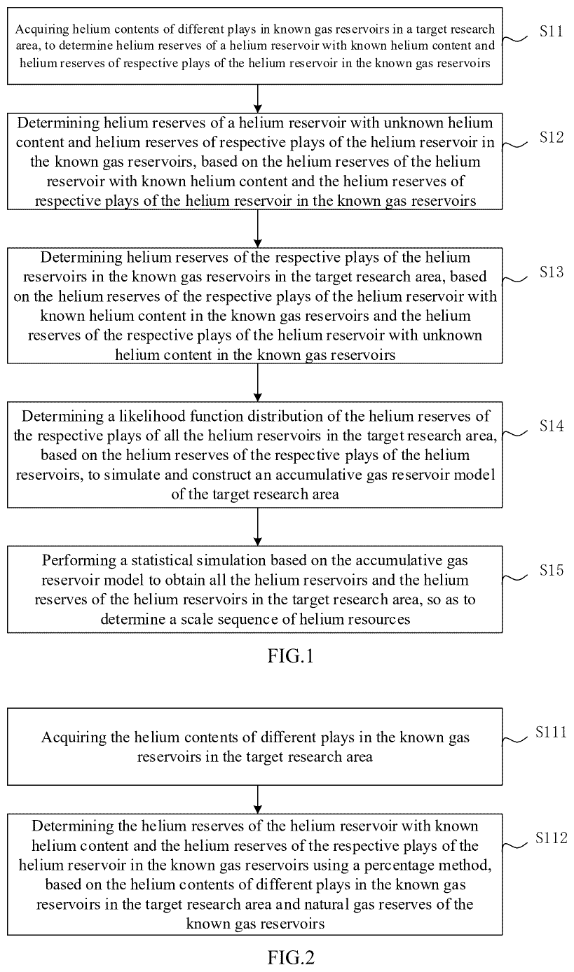

An embodiment of the present disclosure provides a method for determining a scale sequence of helium resources. Referring to FIG. 1, the method may include the following steps:

Step S11: acquiring helium contents of different plays in known gas reservoirs in a target research area, to determine helium reserves of a helium reservoir with known helium content and helium reserves of respective plays of the helium reservoir in the known gas reservoirs.

In this step, the known gas reservoirs in the target research area are taken as the sample data to acquire the helium contents of different plays in the known gas reservoirs. The above gas reservoirs in the embodiments of the present disclosure may be natural gas reservoirs, carbon dioxide gas reservoirs, nitrogen reservoirs, etc., which are not specifically limited in the embodiments of the present disclosure.

In this embodiment, when the sample data is to be acquired, the known gas reservoirs may be sampled to acquire gas samples, and then a helium content detection may be performed on the gas samples using a helium detection device such as a mass spectrometer. In order to improve the accuracy of the helium content detection, an average may be taken after multiple detections.

It should be noted that when the helium contents of different plays in the known gas reservoirs are to be acquired, i.e., during data collection, especially when the same gas reservoir is to be sampled, it is necessary to collect representative gas samples from different parts of the gas reservoir to reduce the system error. If any other data source is used, it is necessary to verify whether the test conditions of respective data points are consistent. The specific sampling requirement may be that the system error of the helium percentage content obtained in the same gas reservoir is less than 10%, and the helium percentage content adopts a weighted average of all the sampling points or data points.

Step S12: determining helium reserves of a helium reservoir with unknown helium content and helium reserves of respective plays of the helium reservoir in the known gas reservoirs, based on the helium reserves of the helium reservoir with known helium content and the helium reserves of respective plays of the helium reservoir in the known gas reservoirs.

This step is based on the analogy method to calculate the helium reserves of the helium reservoir with unknown helium content and helium reserves of respective plays of the helium reservoir in the known gas reservoirs. It should be noted that the helium reservoir with known helium content in the known gas reservoirs in the embodiments of the present disclosure may be simply referred to as a known helium-containing reservoir or a first helium reservoir, and the helium reservoir with unknown helium content in the known gas reservoirs may be simply referred to as a known helium reservoir with unknown helium content or a second helium reservoir.

Step S13: determining helium reserves of the respective plays of the helium reservoirs in the known gas reservoirs in the target research area, based on the helium reserves of the respective plays of the helium reservoir with known helium content in the known gas reservoirs and the helium reserves of the respective plays of the helium reservoir with unknown helium content in the known gas reservoirs.

In this step, the helium reserves of the respective plays of the helium reservoirs in the known gas reservoirs determined using different calculation methods are summarized, i.e., the helium reserves of the first helium reservoir and the second helium reservoir in the respective plays are summarized.

Step S14: determining a likelihood function distribution of the helium reserves of the respective plays of all the helium reservoirs in the target research area, based on the helium reserves of the respective plays of the helium reservoirs, to simulate and construct an accumulative gas reservoir model of the target research area. This step is to simulate the accumulative gas reservoir model of the helium reservoirs in the target research area for the subsequent simulation and evaluation.

Step S15: performing a statistical simulation based on the accumulative gas reservoir model to obtain all the helium reservoirs and the helium reserves of the helium reservoirs in the target research area, so as to determine a scale sequence of helium resources.

This step is to perform a statistical simulation on the accumulative gas reservoir model, so as to estimate the helium reservoirs and the helium reserves of the helium reservoirs in the unknown gas reservoirs in the target research area, and finally determine the scale sequence of helium resources in the target research area.

In the embodiment of the present disclosure, firstly, the known gas reservoirs in the target research area are taken as the sample data, and after the helium contents of different plays in the known gas reservoirs are acquired, the helium reserves of the respective plays of the helium reservoir with known helium content in the known gas reservoirs are determined; during the data collection and the reserve prediction of the helium reservoirs, quantitative analysis is carried out with the respective plays, so that the prediction results are more accurate, and the accuracy of the helium resource evaluation is improved. Next, the helium reserves of the helium reservoir with unknown helium content and the helium reserves of the respective plays of the helium reservoir in the known gas reservoirs are determined based on the helium reserves of the helium reservoir with known helium content and the helium reserves of the respective plays of the helium reservoir in the known gas reservoirs, and the helium reserves of the respective plays of the helium reservoirs in the known gas reservoirs in the target research area are determined by summarization. Next, the accumulative gas reservoir model of the helium reservoirs in the target research area is simulated and constructed based on the known helium reservoirs, and finally, a statistical simulation is performed on the accumulative gas reservoir model to estimate the helium reservoirs and the helium reserves of the helium reservoirs in the unknown gas reservoirs in the target research area, so as to obtain the scale sequence of helium resources in the target research area. This method simulates and constructs the accumulative gas reservoir model, and then predicts the unknown helium reservoirs and the reserves thereof in the research area, which is helpful to analyze the potential and the distribution of the helium resources in the target research area, optimize the favorable enrichment area, and ensure the development and use of the helium resources.

Further, the number and the scales of the discovered helium reservoirs are counted as the basis for the probability estimation of the helium reserves and the resource quantities in the discovered natural gas reserves and the natural gas resources to be discovered. This method may be used as a reliable basis for the evaluation of helium resources and helium assets, the long-term development planning of the helium-containing gas fields and the integration of the full industry chain of helium.

In this embodiment, the following steps may be further included:
determining whether to perform a helium development for the helium reservoirs in the target research area based on the determined scale sequence of helium resources.

Specifically, the following steps may be included:
comparing the helium reserves of all the helium reservoirs in the target research area with a preset developable reserve respectively, and if the helium reserve of a helium reservoir is greater than or equal to the preset developable reserve, deploying exploration wells in the helium reservoir for a helium development; and if the helium reserve of a helium reservoir is less than the preset developable reserve, no helium development is performed for the helium reservoir.

In an optional embodiment, referring to FIG. 2, step S11 may specifically include:
step S111: acquiring the helium contents of different plays in the known gas reservoirs in the target research area; and
step S112: determining the helium reserves of the helium reservoir with known helium content and the helium reserves of the respective plays of the helium reservoir in the known gas reservoirs using a percentage method, based on the helium contents of different plays in the known gas reservoirs in the target research area and natural gas reserves of the known gas reservoirs.

In this step, the helium reserves of the respective plays of the helium reservoir with known helium content (the first helium reservoir) in the known gas reservoirs may be determined by the following formula (I):

$${θ}_{He} = {θ}_{gas} \times {C}_{1} \qquad ( I )$$

in which,
θ_{He} represents a helium reserve of a target gas reservoir, in the unit of m³;
θ_{gas} represents a natural gas reserve of the target gas reservoir, in the unit of m³; and
C₁ represents a helium percentage of the target gas reservoir, in the unit of vol %.

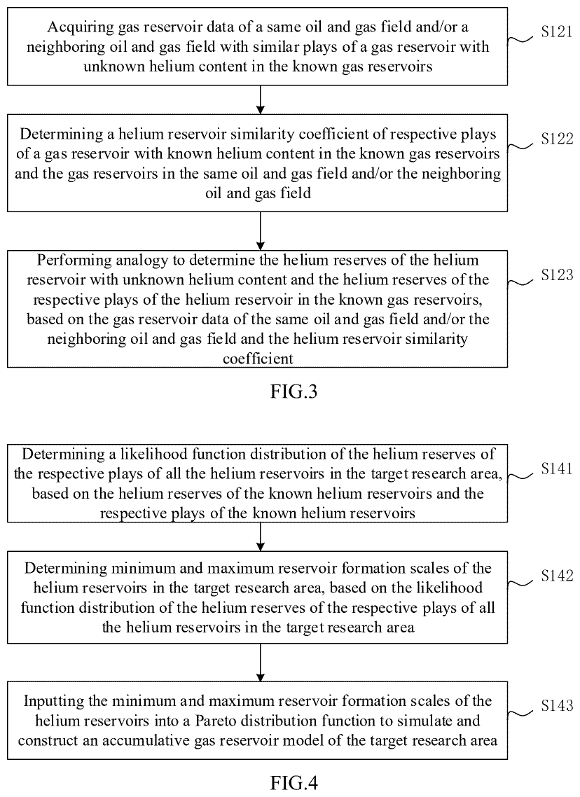

In another optional embodiment, referring to FIG. 3, step S12 may be specifically realized by the following steps:
step S121: acquiring gas reservoir data of a same oil and gas field and/or a neighboring oil and gas field with similar plays of a gas reservoir with unknown helium content in the known gas reservoirs; wherein the gas reservoir data of the same oil and gas field and/or the neighboring oil and gas field includes: a natural gas reserve and a percentage of helium content in the gas reservoir;
step S122: determining a helium reservoir similarity coefficient of respective plays of a gas reservoir with known helium content in the known gas reservoirs and the gas reservoirs in the same oil and gas field and/or the neighboring oil and gas field; and
step S123: performing analogy to determine the helium reserves of the helium reservoir with unknown helium content and the helium reserves of the respective plays of the helium reservoir in the known gas reservoirs, based on the gas reservoir data of the same oil and gas field and/or the neighboring oil and gas field and the helium reservoir similarity coefficient.

In this step, the helium reserves of the respective plays of the helium reservoir with unknown helium content (the second helium reservoir) in the known gas reservoirs may be determined by the following formula (II):

$${θ}_{He 1} = {θ}_{gas 1} \times C \times \text{?} \qquad ( II )$$

in which,
θ_{He1} represents a helium reserve of a target gas reservoir, in the unit of m³;
θ_{gas1} represents a helium natural gas reserve of the target gas reservoir, in the unit of m³;
C represents a helium percentage in an analogy gas reservoir, in the unit of vol %; and
[symbol] represents a similarity coefficient of two helium-containing reservoirs, dimensionless.

In a specific embodiment, before step S121 is performed, it is also necessary to analyze reservoir formation characteristics of helium reservoirs for the respective plays with unknown helium contents in the known gas reservoirs, to determine gas reservoirs with reservoir formation characteristics similar to those of the respective plays with unknown helium contents in the known gas reservoirs.

It should be noted that this step is to analyze the reservoir formation characteristics of different helium reservoirs for the helium-containing gas reservoir with unknown helium content, and determine the helium reserves of the helium-containing gas reservoir with unknown helium content by analogy with the gas reservoirs of other series of strata in the same gas field or the neighboring gas field with known helium reserves.

Step S13 is to summarize the plays of the first helium reservoir in step S11 and the second helium reservoir in step S12, and the result may be determined by the following formula (III):

$${θ}_{He 1} = N \times {θ}_{H e 2} \qquad ( III )$$

in which,
N represents the number of the plays;
θ_{He1} represents a summarized helium reserve of the plays, in the unit of m³; and
θ_{He2} represents a helium reserve of a single play, in the unit of m³.

In another optional embodiment, as illustrated in FIG. 4, simulating and constructing the accumulative gas reservoir model of the target research area in step S14 may specifically include the following steps:

step S141: determining a likelihood function distribution of the helium reserves of the respective plays of all the helium reservoirs in the target research area, based on the helium reserves of the known helium reservoirs and the respective plays of the known helium reservoirs.

In the embodiment of the present disclosure, if the known helium reservoirs in the target research area are valued as x₁, x₂, x₃, . . . , xₙ, a probability of discovering the helium reservoir {X₁=x₁, X₂=x₂, . . . , Xₙ=xₙ} is as follows with reference to Formula (IV):

$$L ( θ ) = L ( {x}_{1} , {x}_{2} , … , {x}_{n} ; θ ) = {\prod }_{\text{?}}^{\text{?}} p ( {x}_{i} ; θ ) \qquad ( IV )$$

$$\text{?} \text{indicates text missing or illegible when filed}$$

in which,
n represents the number of the plays;
L represents a likelihood probability, dimensionless;
X₁, X₂, X₃, . . . , Xₙ represent helium reservoirs in the sample;
X₁, X₂, . . . , Xₙ represent discrete random variables;
P represents a probability, dimensionless; and
θ represents a helium reserve of a helium reservoir, in the unit of m³.

As can be seen from the above formula IV, the probability varies with the helium reserve θ of the helium reservoir.

Step S142: determining minimum and maximum reservoir formation scales of the helium reservoirs in the target research area, based on the likelihood function distribution of the helium reserves of the respective plays of all the helium reservoirs in the target research area.

In this step, the maximum likelihood value of the parameter θ is calculated using a maximum likelihood estimation method, which is to select a parameter value that maximizes L(θ) as an estimated value of the parameter θ within a possible value range of the parameter θ. The maximum likelihood function is as follows with reference to Formula (V):

$$L ( θ ) = L ( {x}_{1} , {x}_{2} , … , {x}_{n} ; \hat{θ} ) = {max}_{θ ∈ Θ} L ( {x}_{1} , {x}_{2} , … , {x}_{n} ; θ ) \qquad ( V )$$

By solving the equation, dL(θ)/dθ=0.

Step S143: inputting the minimum and maximum reservoir formation scales of the helium reservoirs into a Pareto distribution function to simulate and construct an accumulative gas reservoir model of the target research area.

The distribution of the helium reservoirs in the target research area in the embodiment of the present disclosure may be expressed by the truncated Pareto distribution function (TPD), and the truncated Pareto distribution shows a good correspondence between a gas reservoir prediction and an empirical non-normalized accumulative distribution function, referring to Formula (VI) below:

$$φ ( θ ) = \frac{{( {θ}_{\text{?}} )}^{\text{?}} \cdot ( 1 - λ )}{λ \cdot {θ}_{\text{?}} + {θ}_{\text{?}} \cdot [ 1 - λ - {( \frac{{θ}_{\text{?}}}{θ} )}^{\text{?}} ]} \cdot [ \frac{1}{{θ}^{\text{?}}} - \frac{1}{{( {θ}_{\text{?}} )}^{\text{?}}} ] \qquad ( VI )$$

$$\text{?} \text{indicates text missing or illegible when filed}$$

in which,
φ represents a Pareto value, dimensionless;
λ represents a distribution parameter, dimensionless;
θ represents a reserve of a helium reservoir, in the unit of m³;
θ₀ and θₘₐₓ represent minimum and maximum expected reservoir formation scales of naturally accumulated helium reservoirs, respectively.

In another specific embodiment, after step S142 is performed, the method may further include: assigning least square weight values to a distribution parameter, the maximum reservoir formation scale and the number of the plays of the helium reservoirs in the Pareto distribution function, so as to increase the weight of influence of large-scale helium reservoirs in the accumulative gas reservoir model on the accumulative gas reservoir model.

In this step, the complicated problem of λ, θₘₐₓ and N may be simplified to a minimum value of the sum of weighted variances. In this embodiment of the present disclosure, a weight function Pi is introduced. If Pi=(i)−1 or Pi=qi, the data of the large-scale helium reservoirs (of a small number) will have a greater influence on the results, and the case of Pi=1 corresponds to the ordinary least squares, as shown in formula (VII):

$${\sum }_{\text{?}}^{m} {( Φ ( {θ}_{\text{?}} ) - i )}^{2} \cdot {P}_{\text{?}} \to min \qquad ( VII )$$

$$\text{?} \text{indicates text missing or illegible when filed}$$

In a specific embodiment, referring to FIG. 5, step S143 may specifically include:

step S1431: inputting the minimum and maximum reservoir formation scales of the helium reservoirs into a Pareto distribution function;

step S1432: presetting a predetermined number of maximum helium reservoir accumulation areas as the distribution parameter of the distribution of the helium reservoirs.

According to the laws of helium exploration and discovery, the largest helium reservoir will be discovered at first. Therefore, in a zone with a high exploration degree, it may be assumed that a certain number of maximum helium accumulation areas have been discovered, the parameter distribution of the continuous helium reservoirs may adopt a subset m (m>3) of the discovered largest helium reservoir, and the stability of parameter estimation may be used as a sufficient criterion for the selection of the value of m.

A non-standardized accumulative distribution function is calculated from formula (VIII).

$$Φ ( θ ) = N \cdot {\int }_{\text{?}}^{\text{?}} φ ( x ) dx \qquad ( VIII )$$

$$\text{?} \text{indicates text missing or illegible when filed}$$

in which,
the function φ(θ) represents the number of cumulants equal to or greater than θ;
N represents a total number of times of accumulations in the system;
θ represents a helium reserve in a helium reservoir, in the unit of m³.

Step S1433: simulating the Pareto distribution function to identify the helium reservoirs and the helium reserves in a number greater than the predetermined number in the target research area.

It should be noted that after identifying the helium reservoirs and the helium reserves in a number greater than the predetermined number in the target research area, the identified helium reservoirs are sorted and numbered according to the scale of helium reserves of the identified helium reservoirs, so as to simulate and construct the accumulative gas reservoir model.

For example, all the helium reservoirs identified in a specific helium system will be numbered from the largest scale. It is assumed that at least m helium reservoirs are identified in the level of the largest scale, and θ₁≥θ₂≥ . . . ≥θₘ.

Step S1434: simulating and constructing the accumulative gas reservoir model of the target research area, based on the identified helium reservoirs and the helium reserves of the identified helium reservoirs.

In a case where the function φ(θ) is introduced, the parameters λ, θmax and N are introduced to describe the related characteristics of a natural cluster of the helium reservoirs, so that the non-standardized value of the i-th helium reservoir is close to the number i to some extent, as shown in formula (IX):

$$Φ ( {θ}_{\text{?}} ) \approx i , i = 1 … m . \qquad ( IX )$$

$$\text{?} \text{indicates text missing or illegible when filed}$$

In this step, after the parameters of the truncated Pareto distribution (1) are calculated, a series of accumulative gas reservoir models are generated using a simulation method. Simulation is made in each case until m gas reservoirs with the reserves greater than the reserve θ(m) of the m-th gas reservoir in the natural cluster are obtained. For some gas reservoirs with the reserves less than θ(m), the reserves of the helium reservoirs may be calculated according to the helium concentration empirical distribution.

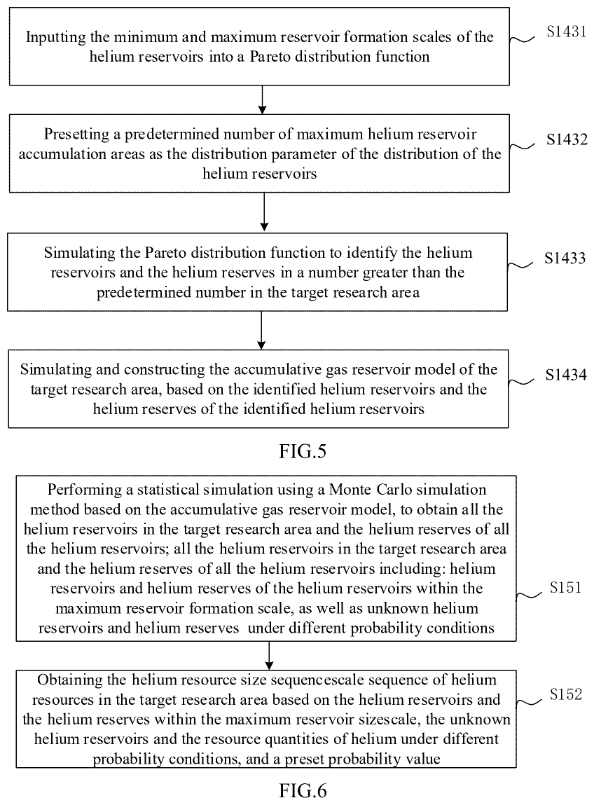

In another optional embodiment, referring to FIG. 6, step S15 may specifically include:

Step S151: performing a statistical simulation using a Monte Carlo simulation method based on the accumulative gas reservoir model, to obtain all the helium reservoirs in the target research area and the helium reserves of all the helium reservoirs; all the helium reservoirs in the target research area and the helium reserves of all the helium reservoirs including: helium reservoirs and helium reserves of the helium reservoirs within the maximum reservoir formation scale, as well as unknown helium reservoirs and helium reserves under different probability conditions.

In this step, the number of gas reservoirs expected to be discovered under different minimum gas reservoir scales are counted. For example, simulation is performed for 5000 times by the Monte Carlo method to generate a geological resource distribution of free gas and helium within a maximum free gas reserve scale, as well as all in-situ prospective resource quantities of free gas and helium in the oil and gas reservoirs to be discovered under different probability conditions, so as to determine the helium reserves and the resource quantities of different levels.

Step S152: obtaining the scale sequence of helium resources in the target research area based on the helium reservoirs and the helium reserves within the maximum reservoir scale, the unknown helium reservoirs and the resource quantities of helium under different probability conditions, and a preset probability value.

The embodiment of the present disclosure may be adopted to calculate the helium-containing natural gas reserves with known helium content, the known gas reservoir reserves with unknown helium content, and the geological resource quantity distribution of the helium-containing natural gas in the gas reservoirs to be discovered. The helium reservoirs with the reserves less than the minimum scale reserve will be truncated on the left side of the Pareto distribution.

The empirical data used in this method may represent various helium reservoirs with different distribution characteristics and the research and understanding degree of these helium reservoirs, such as different strata, lithologies, structures and composite oil and gas reservoirs. The degree of deviation in the estimation of reserves and resource quantity is related to the exploration maturity of the oilfield.

In a specific example, description is given as follows by taking a certain target research area as an instance.

The helium data and helium contents of different (e.g., 4) plays in the known gas reservoirs are collected. In the research area, 78 oil and gas fields are discovered, in which 332 gas reservoirs in 68 oil fields have reserve data, 245 gas reservoirs in 32 oil fields have helium content data, and 87 gas reservoirs in 13 gas fields are known to contain helium without helium content data. The helium reserves in the helium-containing reservoirs with known helium content are calculated using a percentage method, a summary sheet 1 (Table 1) of known helium reserves of 4 plays is obtained according to formula (I), and the known original geological reserve of helium in the research area is 19.95 billion cubic meters. For the helium-containing reservoirs with unknown helium content, an analogy research is carried out between the free gas reservoirs in 13 gas fields and the known helium reservoirs, the helium contents of 87 gas reservoirs are determined, the reserves of the target helium reservoirs (Table 1) are obtained according to formula (II), and the original geological reserve of helium in the research area calculated by analogy is 5.71 billion cubic meters.

TABLE 1
Summary Sheet of Known Helium Reserves of
Different Plays in the Target Research Area

| | | Reserve of | Helium | Weighted |
|---|---|---|---|---|
| | | free natural | reserve, | helium |
| Play | | gas, Tcm | Bcm | content |
| Play 1 | Gas reservoir with | 0.47 | 0.75 | 0.160% |
| | known helium content | | | |
| | Gas reservoir with | 0.03 | 0.05 | 0.167% |
| | analogy helium content | | | |
| Play 2 | Gas reservoir with | 3.30 | 9.27 | 0.281% |
| | known helium content | | | |
| | Gas reservoir with | 1.52 | 3.94 | 0.259% |
| | analogy helium content | | | |
| Play 3 | Gas reservoir with | 2.06 | 9.34 | 0.453% |
| | known helium content | | | |
| | Gas reservoir with | 0.46 | 1.27 | 0.276% |
| | analogy helium content | | | |
| Play 4 | Gas reservoir with | 0.30 | 0.59 | 0.197% |
| | known helium content | | | |
| | Gas reservoir with | 0.17 | 0.45 | 0.264% |
| | analogy helium content | | | |
| Total | Gas reservoir with | 6.13 | 19.95 | 0.325% |
| | known helium content | | | |
| | Gas reservoir with | 2.18 | 5.71 | 0.262% |
| | analogy helium content | | | |
| | All the helium- | 8.31 | 25.66 | 0.309% |
| | containing reservoirs | | | |

The known helium reserves and the analogy helium reserves of respective plays are counted, the helium reserves of different plays are summarized, and the weighted helium content is obtained according to formula (III) (Table 1). The total helium reserve in the research area is 25.66 billion cubic meters, and the weighted helium content is 0.309%.

As an exemplary embodiment of the present disclosure, in step S105, after the likelihood function approximate distribution is used, the maximum likelihood is 100 million cubic meters according to formulas (IV) and (V).

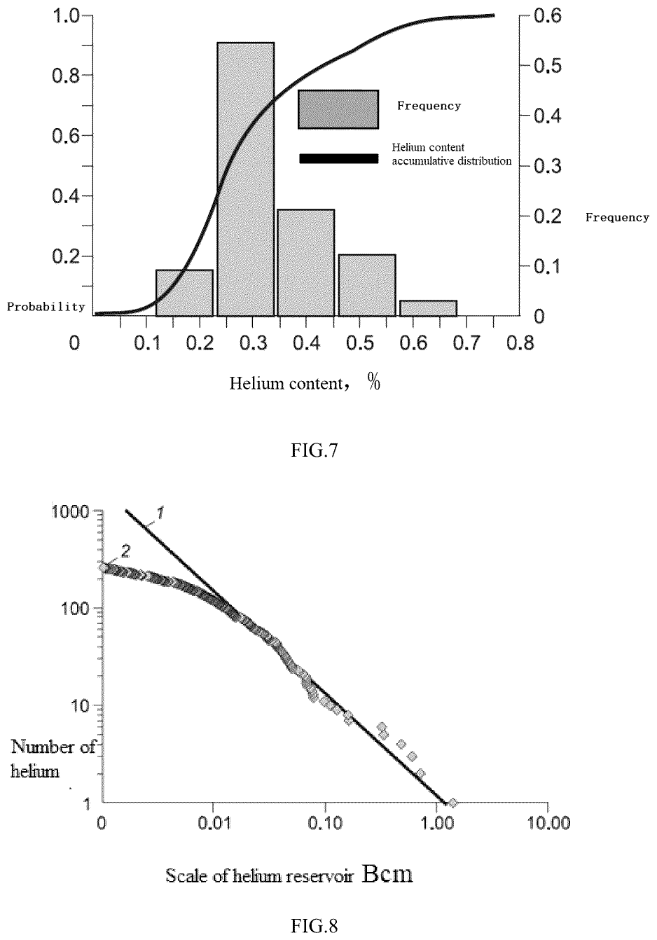

As an exemplary embodiment of the present disclosure, in step S105, after the parameters of the truncated Pareto distribution (1) are calculated, according to formulas (VI), (VII) and (VIII), a series of analog accumulative gas reservoirs are generated using an analog simulation method. If the minimum helium reservoir scale θ₀ is 3 million cubic meters (the number of gas reservoirs smaller than this scale is known to be 15), it is expected that the number N of the discovered gas reservoirs is 12250 (the number of the discovered gas reservoirs is 336), and if the minimum gas reservoir scale θ₀ is 30 million cubic meters (the number of gas reservoirs smaller than this scale is known to be 317), it is expected that the number N of the discovered gas reservoirs is 1320, thereby forming the free gas helium concentration histogram and the accumulative distribution map in the research area as illustrated in FIG. 7.

Based on the Monte Carlo method, the distribution of original geological reserves of helium is deduced from the helium reserves in the known gas reservoirs. In the research area, there are 90 largest gas reservoirs with the helium reserves greater than 300 million cubic meters, and in the parameters of the truncated Pareto distribution, I is estimated as 1.98 and θₘₐₓ is estimated as 12 billion cubic meters. As illustrated in FIG. 8, the gas reservoirs with the reserves less than 300 million cubic meters show a good correspondence between a gas reservoir prediction and an empirical non-normalized accumulative distribution function.

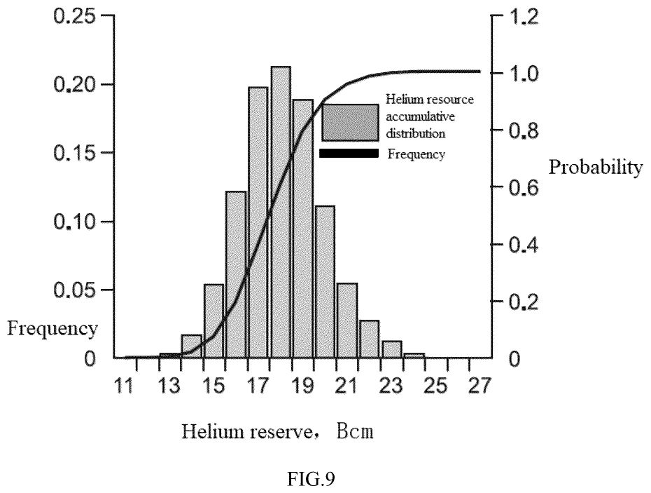

Simulation is performed for 5000 times by the Monte Carlo method to generate a frequency and approximate accumulative distribution of helium resources with in-situ free gas reserves less than 300 million cubic meters in the research area as illustrated in FIG. 9, and the total helium reserve of the discovered gas reservoirs corresponding to the reserve scale is 300 million cubic meters. The total in-situ prospective resource quantity of the helium reservoirs to be discovered has a probability estimated value of 0.9, a minimum value of 12.3 billion cubic meters and a maximum value of 17 billion cubic meters (Table 2). If a median P50 is taken, the prospective resource quantity of helium in the 4 plays in the research area is 14.6 billion cubic meters, and a sum of all the in-situ reserves and prospective resource quantities of helium is 40.2 billion cubic meters (Table 3).

TABLE 2
In-Situ Resources of Free Natural
Gas and Helium in the Research Area

| | Resource quantity | |
|---|---|---|
| Probability | of free natural | Resource quantity |
| distribution | gas, Tcm | of helium, Bcm |
| P50 | 4.8 | 14.6 |
| P10 | 5.7 | 17.0 |
| P90 | 4.1 | 12.3 |
| P5 | 5.9 | 17.9 |
| P95 | 3.9 | 11.7 |
| P2.5 | 6.1 | 18.5 |
| P97.5 | 3.7 | 11.2 |

TABLE 3
List of Reserves and Resource Quantities of Helium
in Different Plays in The Research Area

| | Reserve | Known | Analogy | Prospective | All the |
|---|---|---|---|---|---|
| | of free | helium | helium | resource | helium |
| | natural | reserve, | reserve, | quantity, | resources, |
| Play | gas, Tcm | Bcm | Bcm | Bcm | Bcm |
| Play 1 | 0.5 | 0.75 | 0.05 | 0.55 | 1.35 |
| Play 2 | 4.82 | 9.27 | 3.94 | 6.78 | 19.99 |
| Play 3 | 2.52 | 9.34 | 1.27 | 6.84 | 17.45 |
| Play 4 | 0.64 | 0.59 | 0.45 | 0.43 | 1.47 |
| Total | 8.31 | 19.95 | 5.71 | 14.6 | 40.26 |

It should be noted that the instance data used in the embodiments of the present disclosure is very close to the truncated Pareto distribution. However, from the theoretical analysis, the actual distribution pattern of the helium reservoirs may be various, and the distribution pattern of the helium reservoirs at a specific scale is not necessarily the Pareto distribution. In the classical theoretical model of oil and gas reservoir formation scale distribution, the scales of small oil and gas reservoirs may be deviated from the Pareto distribution.

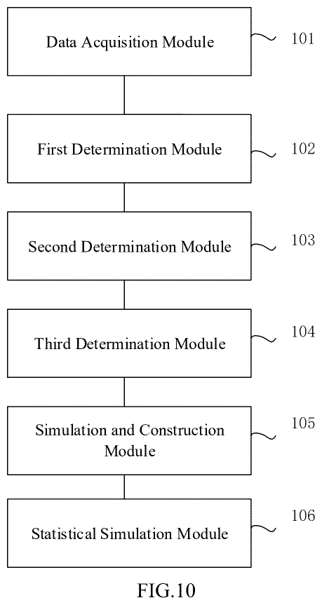

Based on the same inventive concept, an embodiment of the present disclosure further provides an apparatus for determining a scale sequence of helium resources. Referring to FIG. 10, the apparatus may include a data acquisition module 101, a first determination module 102, a second determination module 103, a third determination module 104, a simulation and construction module 105 and a statistical simulation module 106, and the working principle is as follows:
the data acquisition module 101 is configured to acquire helium contents of different plays in known gas reservoirs in a target research area;
the first determination module 102 is configured to determine helium reserves of a helium reservoir with known helium content and helium reserves of respective plays of the helium reservoir in the known gas reservoirs, based on the helium contents of different plays in the known gas reservoirs;
the second determination module 103 is configured to helium reserves of a helium reservoir with unknown helium content and helium reserves of respective plays of the helium reservoir in the known gas reservoirs, based on the helium reserves of the helium reservoir with known helium content and the helium reserves of respective plays of the helium reservoir in the known gas reservoirs;
the third determination module 104 is configured to determine helium reserves of the respective plays of the helium reservoirs in the known gas reservoirs in the target research area, based on the helium reserves of the respective plays of the helium reservoir with known helium content in the known gas reservoirs and the helium reserves of the respective plays of the helium reservoir with unknown helium content in the known gas reservoirs;
the simulation and construction module 105 is configured to determine a likelihood function distribution of the helium reserves of the respective plays of all the helium reservoirs in the target research area, based on the helium reserves of the respective plays of the helium reservoirs, to simulate and construct an accumulative gas reservoir model of the target research area; and
the statistical simulation module 106 is configured to perform a statistical simulation based on the accumulative gas reservoir model to obtain all the helium reservoirs and the helium reserves of the helium reservoirs in the target research area, so as to determine a scale sequence of helium resources.

In an optional embodiment, the first determination module 102 is specifically configured to determine the helium reserves of the helium reservoir with known helium content and the respective plays of the helium reservoir in the known gas reservoirs using a percentage method, based on the helium contents of different plays in the known gas reservoirs in the target research area and natural gas reserves of the known gas reservoirs.

In another optional embodiment, the data acquisition module 101 is further configured to obtain gas reservoir data of a same oil and gas field and/or a neighboring oil and gas field with similar plays of a gas reservoir with unknown helium content in the known gas reservoirs; in which the gas reservoir data of the same oil and gas field and/or the neighboring oil and gas field includes: a natural gas reserve and a percentage of helium content in the gas reservoir;

the second determination module 103 is configured to determine respective plays of a gas reservoir with known helium content in the known gas reservoirs and a helium reservoir similarity coefficient of the gas reservoirs in the same oil and gas field and/or the neighboring oil and gas field; and perform analogy to determine the helium reserves of the helium reservoir with unknown helium content and the respective plays of the helium reservoir in the known gas reservoirs, based on the gas reservoir data of the same oil and gas field and/or the neighboring oil and gas field and the helium reservoir similarity coefficient.

Specifically, before acquiring the gas reservoir data of the same oil and gas field and/or the neighboring oil and gas field, the data acquisition module 101 further analyzes reservoir formation characteristics of helium reservoirs for the respective plays with unknown helium contents in the known gas reservoirs, to determine gas reservoirs with reservoir formation characteristics similar to those of the respective plays with unknown helium contents in the known gas reservoirs.

In another optional embodiment, the simulation and construction module 105 is specifically configured to determine a likelihood function distribution of the helium reserves of the respective plays of all the helium reservoirs in the target research area, based on the helium reserves of the known helium reservoirs and the respective plays of the known helium reservoirs; determine minimum and maximum reservoir formation scales of the helium reservoirs in the target research area, based on the likelihood function distribution of the helium reserves of the respective plays of all the helium reservoirs in the target research area; and

input the minimum and maximum reservoir formation scales of the helium reservoirs into a Pareto distribution function, and simulate and construct an accumulative gas reservoir model of the target research area.

In another optional embodiment, the simulation and construction module 105 is further configured to assign least square weight values to a distribution parameter, the maximum reservoir formation scale and the number of the plays of the helium reservoirs in the Pareto distribution function, so as to increase the weight of influence of large-scale helium reservoirs in the accumulative gas reservoir model on the accumulative gas reservoir model.

In another specific embodiment, the simulation and construction module 105 is further configured to input the minimum and maximum reservoir formation scales of the helium reservoirs into a Pareto distribution function;

preset a predetermined number of maximum helium reservoir accumulation areas as the distribution parameter of the distribution of the helium reservoirs;

simulate the Pareto distribution function to identify the helium reservoirs in a number greater than the predetermined number in the target research area and the helium reserves thereof; and

simulate and construct the accumulative gas reservoir model of the target research area, based on the identified helium reservoirs and the helium reserves of the identified helium reservoirs.

In another specific embodiment, after identifying the helium reservoirs in a number greater than the predetermined number in the target research area and the helium reserves of the helium reservoirs, the simulation and construction module 105 is further configured to sort and number the identified helium reservoirs based on the helium reserves of the identified helium reservoirs, so as to simulate and construct the accumulative gas reservoir model.

In another optional embodiment, the statistical simulation module 106 is specifically configured to perform a statistical simulation using a Monte Carlo simulation method based on the accumulative gas reservoir model, to obtain all the helium reservoirs in the target research area and the helium reserves of the helium reservoirs; all the helium reservoirs in the target research area and the helium reserves thereof including: helium reservoirs and helium reserves of the helium reservoirs within the maximum reservoir formation scale, as well as unknown helium reservoirs and resource quantities of helium under different probability conditions; and

obtain the scale sequence of helium resources in the target research area based on the helium reservoirs and the helium reserves within the maximum reservoir scale, the unknown helium reservoirs and the resource quantities of helium under different probability conditions, and a preset probability value.

Based on the same inventive concept, an embodiment of the present disclosure further provides a computer-readable storage medium which stores a computer program, wherein when executed by a processor, the computer program implements the aforementioned method for determining the scale sequence of helium resources.

Based on the same inventive concept, an embodiment of the present disclosure further provides a computer device, including a memory, a processor and a computer program which is stored in the memory and runnable on the processor, wherein when executing the computer program, the processor implements the aforementioned method for determining the scale sequence of helium resources.

The principle of solving the problems by the aforementioned apparatus, medium and related device in the embodiments of the present disclosure is similar to that of the method, so the implementation thereof can refer to that of the method, which is not repeated here.

Persons skilled in the art should appreciate that any embodiment of the present disclosure can be provided as a method, a system or a computer program product. Therefore, the present disclosure can take the form of a full hardware embodiment, a full software embodiment, or an embodiment combining software and hardware. Moreover, the present disclosure can take the form of a computer program product implemented on one or more computer usable storage mediums (including, but not limited to, a magnetic disc memory, optical storage, etc.) containing therein computer usable program codes.

The present disclosure is described with reference to a flowchart and/or a block diagram of the method, device (system) and computer program product according to the embodiments of the present disclosure. It should be appreciated that each flow and/or block in the flowchart and/or the block diagram and a combination of flows and/or blocks in the flowchart and/or the block diagram can be realized by computer program instructions. Those computer program instructions can be provided to a general computer, a dedicated computer, an embedded processor or a processor of other programmable data processing device to produce a machine, so that the instructions executed by the processor of the computer or other programmable data processing device produce means for realizing specified functions in one or more flows in the flowchart and/or one or more blocks in the block diagram.

These computer program instructions may also be stored in a computer readable memory capable of guiding the computer or other programmable data processing devices to work in a particular manner, so that the instructions stored in the computer readable memory can produce manufacture articles including an instructing device which realizes function(s) specified in one or more flows in the flowchart and/or one or more blocks in the block diagram.

These computer program instructions may also be loaded onto the computer or other programmable data processing devices, so that a series of operation steps are performed on the computer or other programmable data processing devices to produce a processing realized by the computer, thus the instructions executed on the computer or other programmable devices provide step(s) for realizing function(s) specified in one or more flows in the flowchart and/or one or more blocks in the block diagram.

Obviously, various modifications and variations can be made to the present disclosure by persons skilled in the art without departing from the spirit and scope of the present disclosure. Thus, if these modifications and variations of the present disclosure fall within the scope of the claims of the present disclosure and their technical equivalents, the present disclosure is also intended to include these modifications and variations.

1. A method for determining a scale sequence of helium resources, comprising:
acquiring helium contents of different plays in known gas reservoirs in a target research area, to determine helium reserves of a helium reservoir with known helium content and helium reserves of respective plays of the helium reservoir in the known gas reservoirs;
determining helium reserves of a helium reservoir with unknown helium content and helium reserves of respective plays of the helium reservoir in the known gas reservoirs, based on the helium reserves of the helium reservoir with known helium content and the helium reserves of respective plays of the helium reservoir in the known gas reservoirs;
determining helium reserves of the respective plays of the helium reservoirs in the known gas reservoirs in the target research area, based on the helium reserves of the respective plays of the helium reservoir with known helium content in the known gas reservoirs and the helium reserves of the respective plays of the helium reservoir with unknown helium content in the known gas reservoirs;
determining a likelihood function distribution of the helium reserves of the respective plays of all the helium reservoirs in the target research area, based on the helium reserves of the respective plays of the helium reservoirs, to simulate and construct an accumulative gas reservoir model of the target research area; and
performing a statistical simulation based on the accumulative gas reservoir model to obtain all the helium reservoirs and the helium reserves of the helium reservoirs in the target research area, so as to determine a scale sequence of helium resources.

2. The method according to claim 1, wherein the acquiring helium contents of different plays in known gas reservoirs in a target research area, to determine helium reserves of a helium reservoir with known helium content and helium reserves of respective plays of the helium reservoir in the known gas reservoirs comprises:
acquiring the helium contents of different plays in the known gas reservoirs in the target research area; and
determining the helium reserves of the helium reservoir with known helium content and the helium reserves of the respective plays of the helium reservoir in the known gas reservoirs using a percentage method, based on the helium contents of different plays in the known gas reservoirs in the target research area and natural gas reserves of the known gas reservoirs.

3. The method according to claim 1, wherein the determining helium reserves of a helium reservoir with unknown helium content and helium reserves of respective plays of the helium reservoir in the known gas reservoirs, based on the helium reserves of the helium reservoir with known helium content and the helium reserves of the respective plays of the helium reservoir in the known gas reservoirs comprises:
acquiring gas reservoir data of a same oil and gas field and/or a neighboring oil and gas field with similar plays of a gas reservoir with unknown helium content in the known gas reservoirs; wherein the gas reservoir data of the same oil and gas field and/or the neighboring oil and gas field comprises: a natural gas reserve and a percentage of helium content in the gas reservoir;
determining a helium reservoir similarity coefficient of respective plays of a gas reservoir with known helium content in the known gas reservoirs and the gas reservoirs in the same oil and gas field and/or the neighboring oil and gas field; and
performing analogy to determine the helium reserves of the helium reservoir with unknown helium content and the helium reserves of the respective plays of the helium reservoir in the known gas reservoirs, based on the gas reservoir data of the same oil and gas field and/or the neighboring oil and gas field and the helium reservoir similarity coefficient.

4. The method according to claim 3, wherein before the acquiring gas reservoir data of a same oil and gas field and/or a neighboring oil and gas field with similar plays of a gas reservoir with unknown helium content in the known gas reservoirs, the method further comprises:
analyzing reservoir formation characteristics of helium reservoirs for the respective plays with unknown helium contents in the known gas reservoirs, to determine gas reservoirs with reservoir formation characteristics similar to those of the respective plays with unknown helium contents in the known gas reservoirs.

5. The method according to claim 1, wherein the determining a likelihood function distribution of the helium reserves of the respective plays of all the helium reservoirs in the target research area, based on the helium reserves of the respective plays of the helium reservoirs, to simulate and construct an accumulative gas reservoir model of the target research area comprises:
determining a likelihood function distribution of the helium reserves of the respective plays of all the helium reservoirs in the target research area, based on the helium reserves of the known helium reservoirs and the helium reserves of the respective plays of the known helium reservoirs;
determining minimum and maximum reservoir formation scales of the helium reservoirs in the target research area, based on the likelihood function distribution of the helium reserves of the respective plays of all the helium reservoirs in the target research area; and
inputting the minimum and maximum reservoir formation scales of the helium reservoirs into a Pareto distribution function to simulate and construct an accumulative gas reservoir model of the target research area.

6. The method according to claim 5, wherein after the inputting the minimum and maximum reservoir formation scales of the helium reservoirs into a Pareto distribution function to simulate and construct an accumulative gas reservoir model of the target research area, the method further comprises:
assigning least square weight values to a distribution parameter, the maximum reservoir formation scale and the number of the plays of the helium reservoirs in the Pareto distribution function, so as to increase the weight of influence of large-scale helium reservoirs in the accumulative gas reservoir model on the accumulative gas reservoir model.

7. The method according to claim 6, wherein the inputting the minimum and maximum reservoir formation scales of the helium reservoirs into a Pareto distribution function, and simulating and constructing an accumulative gas reservoir model of the target research area comprises:
inputting the minimum and maximum reservoir formation scales of the helium reservoirs into a Pareto distribution function;
presetting a predetermined number of maximum helium reservoir accumulation areas as the distribution parameter of the distribution of the helium reservoirs;
simulating the Pareto distribution function to identify the helium reservoirs and the helium reserves in a number greater than the predetermined number in the target research area; and
simulating and constructing the accumulative gas reservoir model of the target research area, based on the identified helium reservoirs and the helium reserves of the identified helium reservoirs.

8. The method according to claim 7, wherein after the identifying the helium reservoirs and the helium reserves in a number greater than the predetermined number in the target research area, the method further comprises:
sorting and numbering the identified helium reservoirs based on the helium reserves of the identified helium reservoirs, so as to simulate and construct the accumulative gas reservoir model.

9. The method according to claim 1, wherein performing a statistical simulation based on the accumulative gas reservoir model to obtain all the helium reservoirs and the helium reserves thereof in the target research area, so as to determine a scale sequence of helium resources comprises:
performing a statistical simulation using a Monte Carlo simulation method based on the accumulative gas reservoir model, to obtain all the helium reservoirs in the target research area and the helium reserves of all the helium reservoirs; all the helium reservoirs in the target research area and the helium reserves thereof comprising: helium reservoirs and helium reserves thereof within the maximum reservoir formation scale, as well as unknown helium reservoirs and resource quantities of helium under different probability conditions; and
obtaining the scale sequence of helium resources in the target research area based on the helium reservoirs and the helium reserves within the maximum reservoir scale, the unknown helium reservoirs and the resource quantities of helium under different probability conditions, and a preset probability value.

10. An apparatus for determining a scale sequence of helium resources, comprising:
a data acquisition module configured to acquire helium contents of different plays in known gas reservoirs in a target research area;
a first determination module configured to determine helium reserves of a helium reservoir with known helium content and helium reserves of respective plays of the helium reservoir in the known gas reservoirs, based on the helium contents of different plays in the known gas reservoirs;
a second determination module configured to determine helium reserves of a helium reservoir with unknown helium content and helium reserves of respective plays of the helium reservoir in the known gas reservoirs, based on the helium reserves of the helium reservoir with known helium content and the helium reserves of respective plays of the helium reservoir in the known gas reservoirs;
a third determination module configured to determine helium reserves of the respective plays of the helium reservoirs in the known gas reservoirs in the target research area, based on the helium reserves of the respective plays of the helium reservoir with known helium content in the known gas reservoirs and the helium reserves of the respective plays of the helium reservoir with unknown helium content in the known gas reservoirs;
a simulation and construction module configured to determine a likelihood function distribution of the helium reserves of the respective plays of all the helium reservoirs in the target research area, based on the helium reserves of the respective plays of the helium reservoirs, to simulate and construct an accumulative gas reservoir model of the target research area; and
a statistical simulation module configured to perform a statistical simulation based on the accumulative gas reservoir model to obtain all the helium reservoirs and the helium reserves of the helium reservoirs in the target research area, so as to determine a scale sequence of helium resources.

11. A computer-readable storage medium which stores a computer program, wherein when executed by a processor, the computer program implements the method for determining the scale sequence of helium resources according to claim 1.

12. (canceled)
